(19) United States
(12) Patent Application Publication
(10) Pub. No.: US 2026/0208321 A1
(43) Pub. Date: Jul. 23, 2026

(54) MEMBRANE, CHEMICAL MECHANICAL POLISHING APPARATUS INCLUDING THE SAME, AND SUBSTRATE POLISHING METHOD USING THE SAME

(71) Applicant: Samsung Electronics Co., Ltd., Suwon-si (KR)

(72) Inventors: JAEHYEON LIM, Suwon-si (KR); HOYOUNG KIM, Suwon-si (KR); KIHYUN PARK, Suwon-si (KR); JUNHWAN YIM, Suwon-si (KR); SEUNG HOON CHOI, Suwon-si (KR)

(21) Appl. No.: 19/322,876

(22) Filed: Sep. 9, 2025

(30) Foreign Application Priority Data
Jan. 20, 2025 (KR) 10-2025-0007963

(51) Int. Cl. B24D 11/04; B24B 37/24

(52) U.S. Cl. CPC B24D 11/04; B24B 37/24

(57) ABSTRACT

A chemical mechanical polishing apparatus includes a polishing head, a membrane mounted on the bottom surface of the polishing head, and a retainer ring connected to the bottom edge surface of the polishing head and surrounding the membrane, wherein the membrane includes a pressing layer configured to press a substrate, and partitions walls extending upward from the pressing layer, wherein the partition walls form a plurality of unit pressure chambers, each unit pressure chamber having a regular hexagonal shape in a plan view.

### CROSS-REFERENCE TO RELATED APPLICATIONS

This U.S. non-provisional patent application claims priority under 35 U.S.C. § 119 to Korean Patent Application No. 10-2025-0007963, filed on Jan. 20, 2025, the entire content of which is herein incorporated by reference in its entirety.

### BACKGROUND

The present disclosure herein relates to a membrane, a chemical mechanical polishing apparatus including the membrane, and a substrate polishing method using the chemical mechanical polishing apparatus.

Semiconductor devices may be manufactured by several processes. For example, the semiconductor device may be manufactured by performing, on a substrate, a photolithography process, an etching process, and a deposition process. Prior to performing the processes, planarizing process for planarizing the surface of the substrate may be performed. For planarizing the surface of the substrate, a polishing process may be performed on the substrate. The polishing process may be performed in a variety of methods. For example, a chemical mechanical polishing (CMP) process may be used to planarize the substrate.

### SUMMARY

The present disclosure provides a membrane for applying pressure to uniformly polish a substrate, a chemical mechanical polishing apparatus including the membrane, and a substrate polishing method using the chemical mechanical polishing apparatus.

The objects of the inventive concept are not limited to the object mentioned above, but other objects not described herein will be clearly understood by those skilled in the art from the following description.

An embodiment of the inventive concept provides a pressing layer, and a plurality of partition walls extending upward from the pressing layer and connected to each other, wherein the plurality of partition walls, together with the pressing layer, form a plurality of unit pressure chambers, each unit pressure chamber having a regular hexagonal shape in a plan view, and the plurality of unit pressure chambers form a honeycomb structure.

In an embodiment of the inventive concept, a chemical mechanical polishing apparatus includes a polishing head, a membrane mounted on bottom of the polishing head, and a retainer ring connected to bottom edge of the polishing head and surrounding the membrane, wherein the membrane comprises a pressing layer configured to press a substrate, and partitions walls extending upward from the pressing layer, wherein the partition walls form a plurality of unit pressure chambers, each unit pressure chamber having a regular hexagonal shape in a plan view, wherein the plurality of unit pressure chambers form a honeycomb structure, and wherein the polishing head comprises gas feeding lines configured to independently deliver compressed gas to the plurality of unit pressure chambers.

In an embodiment of the inventive concept, a substrate polishing method includes placing a substrate between a membrane of a polishing head of a chemical mechanical polishing apparatus and a polishing pad of the chemical mechanical polishing apparatus, and polishing the substrate with the polishing pad, including expanding a region of the membrane to increase a pressing force of a target region of the substrate on the polishing pad, wherein the expanding the region of the membrane comprises independently supplying compressed gas to unit pressure chambers of the membrane.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept.

In the drawings:

FIG. 1 is a perspective view of a chemical mechanical polishing apparatus according to some embodiments of the inventive concept;

FIG. 2 is a cross-sectional view of a chemical mechanical polishing apparatus according to some embodiments of the inventive concept;

FIG. 3 is a plan view of a membrane according to some embodiments of the inventive concept;

FIG. 4 is a conceptual cross-sectional view of a chemical mechanical polishing apparatus according to some embodiments of the inventive concept;

FIG. 5 is a conceptual cross-sectional view of a chemical mechanical polishing apparatus according to some embodiments of the inventive concept;

FIG. 6 is a conceptual cross-sectional view of a chemical mechanical polishing apparatus according to some embodiments of the inventive concept;

FIG. 7 is a flowchart showing a substrate polishing method according to some embodiments of the inventive concept;

FIG. 8 is a plan view showing an expanding region of a membrane according to a substrate polishing method;

FIG. 9 is a plan view showing an expanding region of a membrane according to a substrate polishing method;

FIG. 10 is a conceptual diagram showing a process in which a unit pressure chamber of a membrane expands;

FIG. 11 is a conceptual diagram showing a membrane before expansion; and

FIG. 12 is a conceptual diagram showing the membrane after expansion.

### DETAILED DESCRIPTION

Hereinafter, embodiments of the inventive concept are described in detail with reference to the drawings.

It will be understood that when an element is referred to as being “connected to” or “connected on” another element, it can be directly connected to or on the other element or intervening elements may be present.

Items described in the singular herein may be provided in plural. Thus, the description of a single item that is provided in plural should be understood to be applicable to the remaining plurality of items unless context indicates otherwise.

It will be understood that, although the terms first, second, third etc. may be used herein to describe various elements or components, these elements or components should not be limited by these terms. Unless the context indicates otherwise, these terms are only used to distinguish one element or component from another element or component. Thus, a first element or component discussed below in one section of the specification could be termed as a second element or component in another section of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other.

Throughout the specification, when a component is described as “including” a particular element or group of elements, it is to be understood that the component is formed of only the element or the group of elements, or the element or group of elements may be combined with additional elements to form the component, unless the context indicates otherwise.

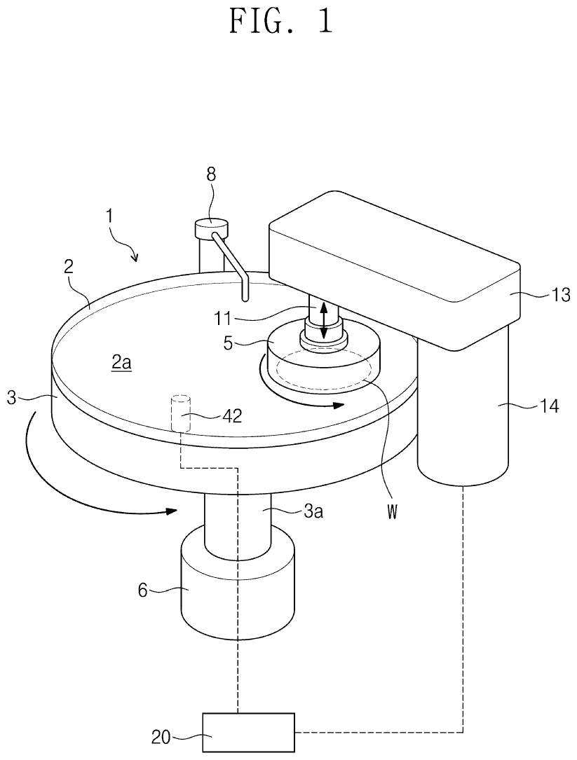

FIG. 1 is a perspective view of a chemical mechanical polishing apparatus according to some embodiments of the inventive concept.

Referring to FIG. 1, a chemical mechanical polishing apparatus 1 may be an apparatus for performing chemical mechanical planarization (CMP) to manufacture a semiconductor device. The chemical mechanical planarization (CMP) is a process to smooth and flatten substrate surfaces. It combines chemical reactions and mechanical abrasion to remove excess material and create a uniform surface. The chemical mechanical planarization (CMP) may be performed through following processes. A specialized slurry containing abrasive particles and reactive chemicals is applied to the substrate. The substate is placed on a rotating pad, and controlled pressure is applied to the substrate to ensure uniform material removal, while the slurry chemically softens the material, making it easier to remove. The abrasive particles in the slurry physically polish the wafer surface. The combination of chemical and mechanical actions results in a smooth, even surface, essential for subsequent semiconductor fabrication steps. After CMP, the substrate undergoes thorough cleaning to remove residual slurry and contaminants.

The chemical mechanical polishing apparatus 1 may include a polishing table 3, a polishing head 5, a polishing liquid supply nozzle 8, a controller 20, and a layer thickness sensor 42.

The polishing table 3 may have a polishing surface 2a. The polishing table 3 may be connected to a table motor 6 below the polishing table 3 via a table shaft 3a. The table motor 6 may be configured to rotate the polishing table 3 and a polishing pad 2 integrally attached on the polishing table 3 in a rotational direction (the direction of an arrow). The surface of the polishing pad 2 may be the polishing surface 2a for polishing a substrate W.

The polishing head 5 may press the substrate W against the polishing surface 2a. The polishing head 5 may be configured to support the substrate W on the lower surface thereof. The substrate W may be, for example, a wafer. The polishing head 5 may be fixed to the end of a polishing head shaft 11. The polishing head shaft 11 may be rotatably supported by a head swing arm 13. The head swing arm 13 may be rotatably supported by a support shaft 14. The polishing head shaft 11 may be connected to a polishing head motor (not shown). The polishing head motor may be configured to rotate the polishing head 5 together with the polishing head shaft 11 in the same direction (the direction of an arrow). The polishing head shaft 11 may be connected to a polishing head vertical movement mechanism (not shown). The polishing head vertical movement mechanism may be configured to vertically move the polishing head shaft 11 and the polishing head 5 relative to the head swing arm 13.

The polishing liquid supply nozzle 8 may supply a polishing liquid onto the polishing surface 2a.

The controller 20 may control operations of the polishing head 5, the table motor 6, the polishing head motor, the polishing head vertical movement mechanism, and the polishing liquid supply nozzle 8. The controller 20 may include at least one computer.

The layer thickness sensor 42 may measure the layer thickness of the substrate W on the polishing surface 2a. The layer thickness sensor 42 may be configured to generate a layer thickness indicator value that directly or indirectly represents the layer thickness of the substrate W. Here, the layer thickness indicator value may change along with variation of the layer thickness of the substrate W. The layer thickness indicator value may represent the layer thickness of the substrate W itself, or may include a physical quantity or a signal value which may be converted to a value indicating the layer thickness. The layer thickness sensor 42 may include, for example, an eddy current sensor or an optical layer thickness sensor. The layer thickness sensor 42 is installed inside the polishing table 3 and may rotate integrally with the polishing table 3. Each time the polishing table 3 rotates, the layer thickness sensor 42 may measure the layer thicknesses at a plurality of measurement points on the substrate W while passing across the substrate W on the polishing surface 2a. The layer thicknesses measured at the plurality of measurement points may be output as layer thickness indicator values, and transmitted to the controller 20. The controller 20 may control the operation of the polishing head 5 on the basis of the layer thickness indicator value.

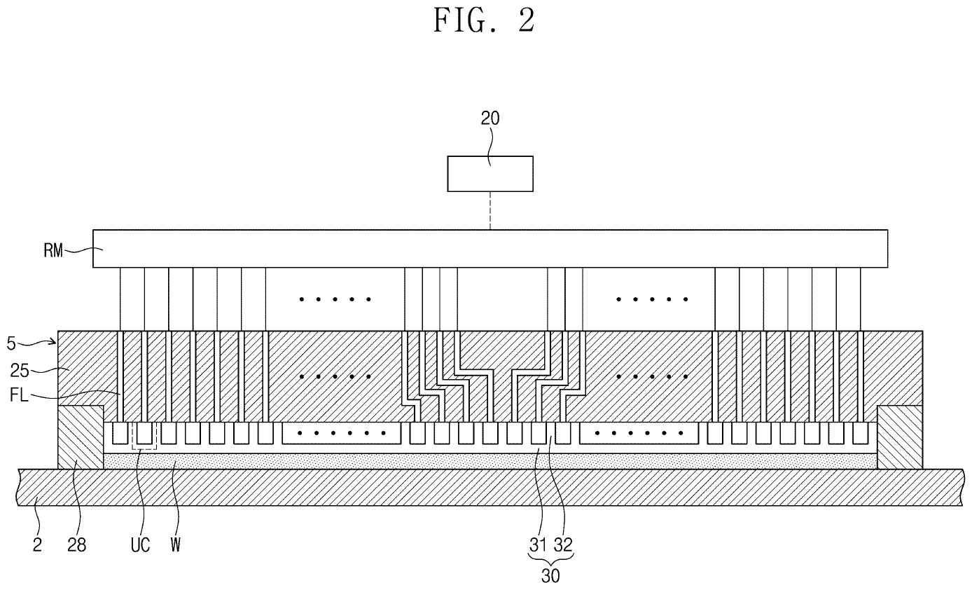

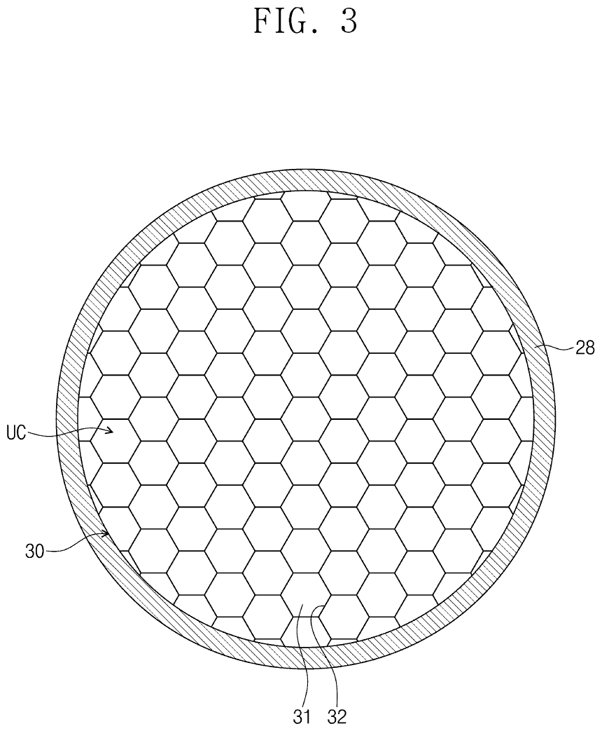

FIG. 2 is a cross-sectional view of a chemical mechanical polishing apparatus according to some embodiments of the inventive concept. FIG. 3 is a plan view of a membrane according to some embodiments of the inventive concept.

Referring to FIG. 1 and FIG. 2, the polishing head 5 may include a carrier 25 fixed to the end of the polishing head shaft 11, a membrane 30 below the carrier 25, and a retainer ring 28 on the lower edge of the carrier 25. The retainer ring 28 may be connected to the lower portion of the carrier 25 and surround the membrane 30. The retainer ring 28 may have a ring-shaped structure that supports and holds the substrate W to prevent the substrate W from moving out from the polishing head 5 during polishing of the substrate W.

Referring to FIG. 2 and FIG. 3, the membrane 30 may include a pressing layer 31 that may be in contact with the upper surface of the substrate W and a plurality of partition walls 32 that extend upwardly from the top surface of the pressing layer 31. The membrane 30 may be formed with an elastic body. Specifically, both the pressing layer 31 and the partition walls 32 may be formed with an elastic body. The elastic body forming the pressing layer 31 and the partition walls 32 may include at least one of polyurethane, silicone rubber, or ethylene propylene diene rubber.

The bottom surface of the pressing layer 31 may be a pressing surface as described herein. The pressing layer 31 may have substantially the same size and shape as the substrate W. The partition walls 32 may be connected to each other to form a unit pressure chamber UC having a regular hexagonal shape in a plan view. A plurality of unit pressure chambers UC may form a honeycomb structure. The membrane may be in a circular shape which is identical with the substrate. Although the edge portion of the membrane may not form regular unit pressure chambers due to the circular shape of the membrane, it may still experience pressure effects through the redundant portions of the pressing layer and the partition walls. Thus, the edge portion may also contribute to the overall pressure response of the membrane. The regular hexagonal structure may minimize the gap between adjacent unit pressure chambers UC. The regular hexagonal structure may have geometric advantages in relation to pressure distribution within the unit pressure chambers UC. The distances from the center of the regular hexagonal structure to partition walls 32 may be relatively uniform. The uniform distances from the center to the partition walls 32 in a hexagonal configuration may lead to more balanced pressure distribution compared to triangular or rectangular shapes, which may have more variability in distance and thus potential inconsistencies in pressure handling.

The plurality of unit pressure chambers UC may be formed by the membrane 30 and the carrier 25. More specifically, each of the plurality of unit pressure chambers UC may be formed by the pressing layer 31 of the membrane 30, the partition walls 32 of the membrane 30, and the carrier 25. Each of the plurality of unit pressure chambers UC may be an enclosed space by the pressing layer 31, the partition walls 32 of the membrane 30, and the carrier 25, and may have substantially the same area with respect to a top down view and have substantially the same volume.

The polishing head 5 may include gas feeding lines FL, which are respectively connected to the unit pressure chambers UC. One end of each of the gas feeding lines FL may be connected to a compressed gas supply source (not shown) that is located in or near the chemical mechanical polishing apparatus 1. The compressed gas may be supplied to each of the unit pressure chambers UC via the gas feeding lines FL.

The compressed gas may be supplied independently to each of the unit pressure chambers UC by a plurality of pressure regulator module RM. Each of the pressure regulator module RM may comprise a diaphragm and valve mechanism, and may adjust pressure of the compressed gas supplied to the unit pressure chamber UC by controlling the valve mechanism.

The pressure regulator module RM may be configured to control the supply of the compressed gas and adjust its pressure level as needed. Accordingly, pressing force may be independently regulated for regions of the substrate W corresponding to the unit pressure chambers UC. The pressure regulator module RM may be controlled by the controller 20. The controller 20 may send a target pressure value for each of the unit pressure chambers UC to the corresponding pressure regulator module RM. The pressure regulator module RM may be operated such that the pressure in the unit pressure chamber UC is maintained at the corresponding target pressure value. Each pressure regulator may be in fluid communication with a corresponding one of the gas feed lines to regulate pressure of the compressed gas within the corresponding gas feed line. The controller 20 may be a processor that is configured to receive layer thickness information of the substrate W, calculate the target pressure value for each of the unit pressure chambers UC based on the received layer thickness information, and transmit the target pressure value to the pressure regulator module RM.

The polishing head 5 may apply independent polishing pressure to each of a plurality of regions on the substrate W. For example, the polishing head 5 may press, by different polishing pressures, different regions of the surface of the substrate W against the polishing surface 2a of the polishing pad 2. Therefore, the polishing head 5 may control a layer thickness profile of the substrate W to achieve a target layer thickness profile.

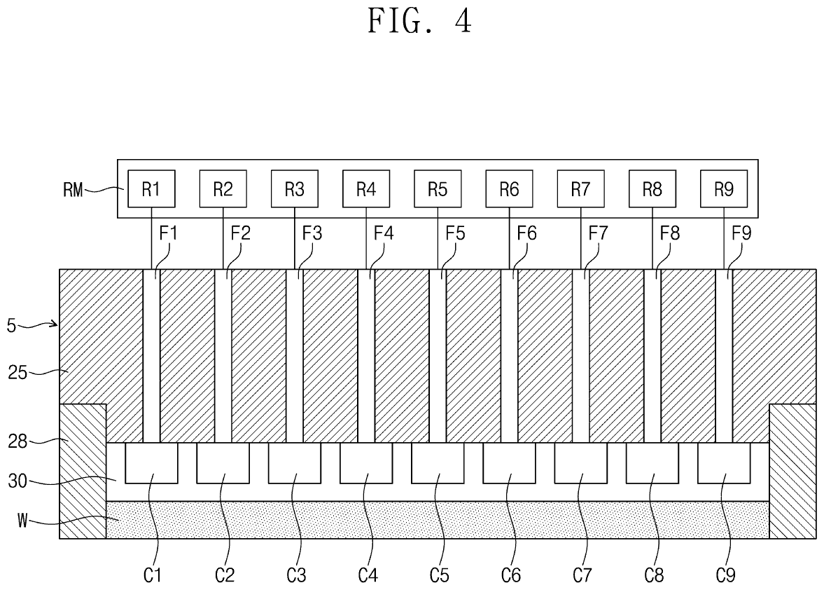

FIG. 4 is a conceptual cross-sectional view of a chemical mechanical polishing apparatus according to some embodiments of the inventive concept.

Referring to FIGS. 3 and 4, the number of gas feeding lines FL may correspond to the number of unit pressure chambers UC. The pressure regulator module RM may include pressure regulators corresponding to the number of unit pressure chambers UC. For example, when the unit pressure chambers UC include first to ninth unit pressure chambers C1, C2, C3, C4, C5, C6, C7, C8, and C9, the gas feeding lines FL may include first to ninth gas feeding lines F1, F2, F3, F4, F5, F6, F7, F8, and F9, and the pressure regulator module RM may include first to ninth pressure regulators R1, R2, R3, R4, R5, R6, R7, R8, and R9. The first to ninth pressure regulators R1 to R9 may regulate the supply of compressed gas delivered to the first to ninth gas feeding lines F1 to F9, respectively and the pressure levels of the compressed gas. The first to ninth unit pressure chambers C1 to C9 are only examples for clear illustration with reference to the drawings, and thus, the number of unit pressure chambers UC may actually be 50 or more as shown in FIG. 3.

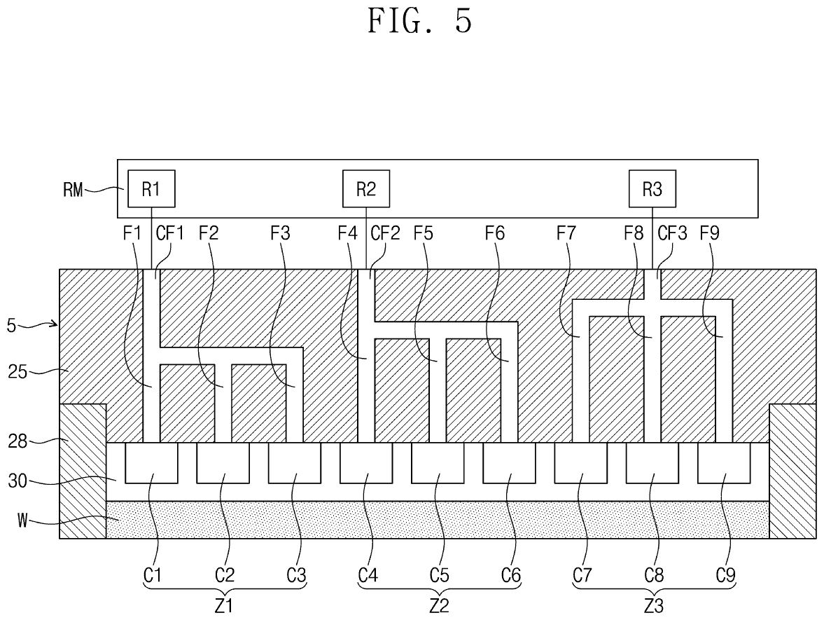

FIG. 5 is a conceptual cross-sectional view of a chemical mechanical polishing apparatus according to some embodiments of the inventive concept.

Referring to FIGS. 3 and 5, the polishing head 5 may include a first common gas feeding line CF1 connected in common to first subset of the gas feeding lines FL, a second common gas feeding line CF2 connected in common to second subset of the gas feeding lines FL, and a third common gas feeding line CF3 connected in common to third subset of the gas feeding lines FL. For example, the first common gas feeding line CF1 may be connected to the first to third gas feeding lines F1, F2, and F3, the second common gas feeding line CF2 may be connected to the fourth to sixth gas feeding lines F4, F5, and F6, and the third common gas feeding line CF3 may be connected to the seventh to ninth gas feeding lines F7, F8, and F9. The first common gas feeding line CF1 may be connected to the first pressure regulator R1, the second common gas feeding line CF2 may be connected to the second pressure regulator R2, and the third common gas feeding line CF3 may be connected to the third pressure regulator R3. The first to third pressure regulators R1 to R3 may independently regulate the supply of compressed gas delivered to the first to third common gas feeding lines CF1 to CF3, respectively, and the pressure levels of the compressed gas. The first to third gas feeding lines F1 to F3 may be supplied with compressed gas substantially at the same time, and the supplied compressed gas may have substantially the same pressure level. The fourth to sixth gas feeding lines F4 to F6 may be supplied with compressed gas substantially at the same time, and the supplied compressed gas may have substantially the same pressure level. The seventh to ninth gas feeding lines F7 to F9 may be supplied with compressed gas substantially at the same time, and the supplied compressed gas may have substantially the same pressure level. The first to third unit pressure chambers C1 to C3 may form a first pressing zone Z1, the fourth to sixth unit pressure chambers C4 to C6 may form a second pressing zone Z2, and the seventh to ninth unit pressure chambers C7 to C9 may form a third pressing zone Z3. The first pressing zone Z1, the second pressing zone Z2, and the third pressing zone Z3 may press different regions on the substrate W.

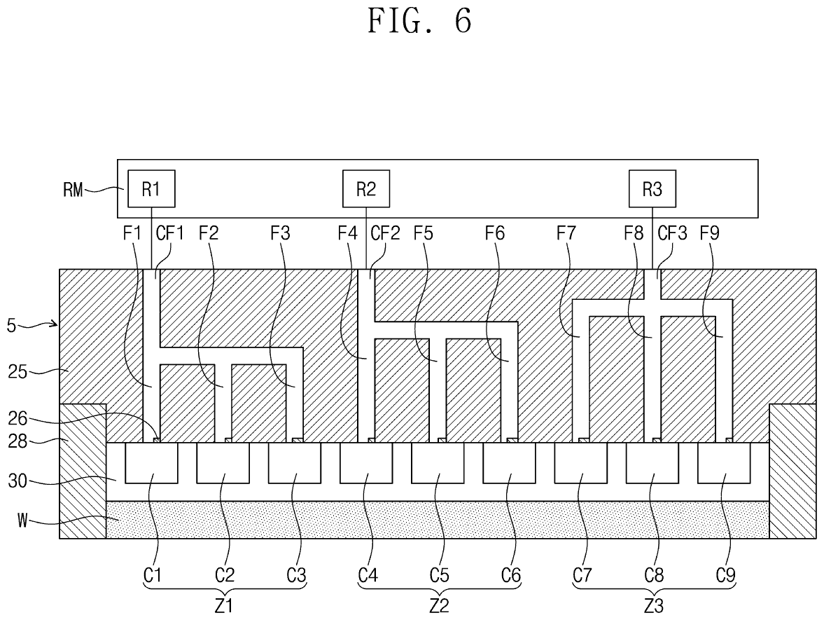

FIG. 6 is a conceptual cross-sectional view of a chemical mechanical polishing apparatus according to some embodiments of the inventive concept. Except for the description below, repeated descriptions such as those given with reference to FIG. 5 are omitted.

Referring to FIGS. 5 and 6, valves 26 may be located inside each of the first to ninth gas feeding lines F1 to F9. The valves 26 may independently adjust the opening sizes of the gas feeding lines FL in a horizontal direction. The valves 26 may be controlled, for example, so that different amounts of compressed gas are delivered to the first to third unit pressure chambers C1 to C3 through the first to third gas feeding lines F1 to F3 connected to the first common gas feeding line CF1. As a result, different pressure may be applied to each of the unit pressure chambers (e.g., C1 and C2) located in the same pressing zone (e.g., Z1), and different levels of pressing force may be applied to different regions of the substrate W. For example, the first pressing zone and the second pressing zone are supplied with the compressed gas at the same pressure during a first time period and at different pressures during a second time period. Furthermore, the first to third unit pressure chambers C1 to C3 of the first pressing zone connected to the first common gas feeding line CF1 may be supplied with the compressed gas at the same pressure during a third time period and at different pressures during a fourth time period.

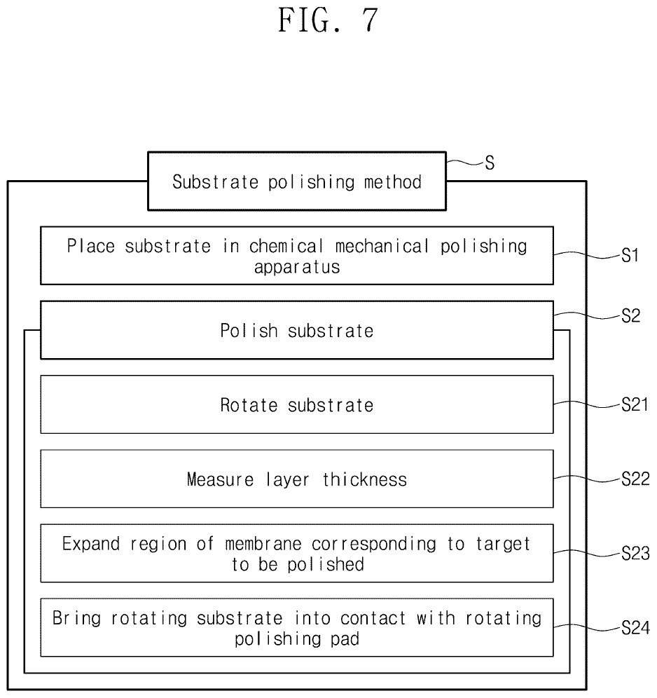

FIG. 7 is a flowchart showing a substrate polishing method according to embodiments of the inventive concept.

Referring to FIG. 7, a substrate polishing method S may use the membrane and the chemical mechanical polishing apparatus including the membrane described with reference to FIGS. 1 to 6.

The substrate polishing method S may include placing the substrate W in the chemical mechanical polishing apparatus 1 (S1) and polishing the substrate W (S2). The polishing (S2) of the substrate W may include rotating the substrate W (S21), measuring the layer thickness of the substrate W (S22), expanding a region of the membrane 30 corresponding to a target region of the substrate W to be polished (S23), and bringing the rotating substrate W into contact with the rotating polishing pad 2 (S24).

Specifically, the polishing (S2) of the substrate W may include supplying the polishing liquid from the polishing liquid supply nozzle 8 to the polishing surface 2a of the polishing pad 2 on the polishing table 3 while rotating the polishing table 3 (S21). The substrate W may be rotated by the polishing head 5 (S22). The unit pressure chamber UC of the membrane 30 corresponding to the target region to be polished of the substrate W, may expand (S23). While the polishing liquid is spread between the polishing pad 2 and the substrate W, the substrate W may be pressed against the polishing surface 2a of the polishing pad 2 by the membrane 30 of the polishing head 5. The surface of the substrate W may be polished by a combination of a chemical action of the polishing liquid and a mechanical action of abrasive grains contained in the polishing liquid and/or the polishing pad 2.

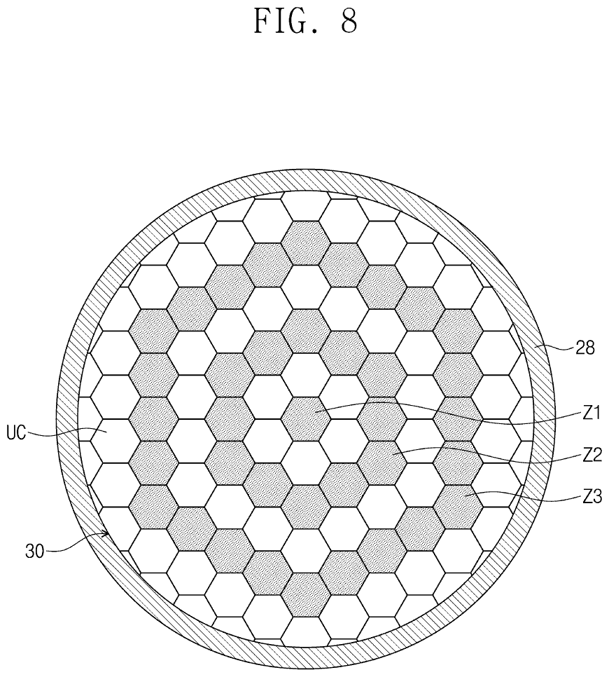

FIG. 8 is a plan view showing an expanding region of a membrane according to a substrate polishing method. Referring to FIG. 8, the first pressing zone Z1, the second pressing zone Z2, and the third pressing zone Z3 of the membrane 30 may represent regions in which the membrane 30 expands.

As in the embodiment described with reference to FIG. 4, each of the unit pressure chambers UC may receive the compressed gas independently from the gas feeding lines FL, thereby forming the first pressing zone Z1, the second pressing zone Z2, and the third pressing zone Z3. Also, as in the embodiment described with reference to FIG. 5, some of the unit pressure chambers UC may be connected to the first common gas feeding line CF1 to form the first pressing zone Z1, other unit pressure chambers UC may be connected to the second common gas feeding line CF2 to form the second pressing zone Z2, and other unit pressure chambers UC may be connected to the third common gas feeding line CF3 to form the third pressing zone Z3. For example, the pressure of the compressed gas delivered to the unit pressure chambers UC arranged in the first pressing zone Z1, the second pressing zone Z2, and the third pressing zone Z3 may be substantially the same.

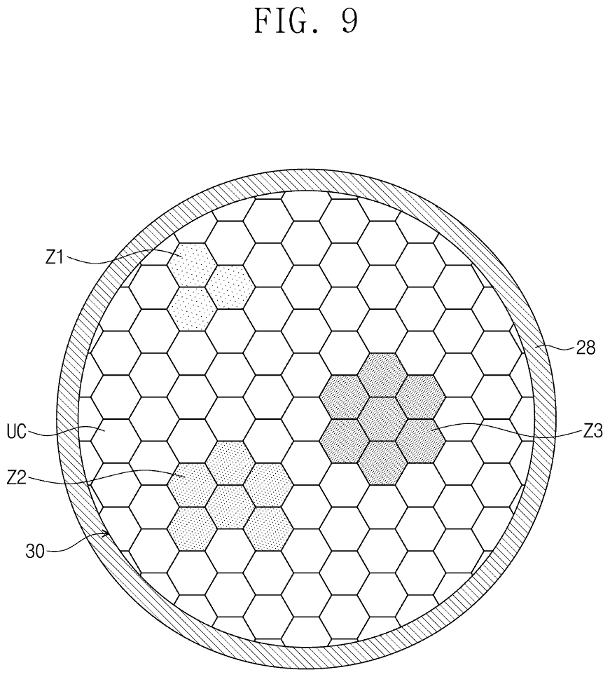

FIG. 9 is a plan view showing an expanding region of a membrane according to a substrate polishing method. Referring to FIG. 8, the first pressing zone Z1, the second pressing zone Z2, and the third pressing zone Z3 of the membrane 30 may each represent a region in which the membrane 30 expands.

As in the embodiment described with reference to FIG. 4, each of the unit pressure chambers UC may independently receive compressed gas to form the first pressing zone Z1, the second pressing zone Z2, and the third pressing zone Z3. The pressures of the compressed gas delivered to the first pressing zone Z1, the second pressing zone Z2, and the third pressing zone Z3 may be different from each other.

Also, as in the embodiment described with reference to FIG. 5, the pressures of the compressed gas delivered via the first common gas feeding line CF1, the second common gas feeding line CF2, and the third common gas feeding line CF3 may be different from each other.

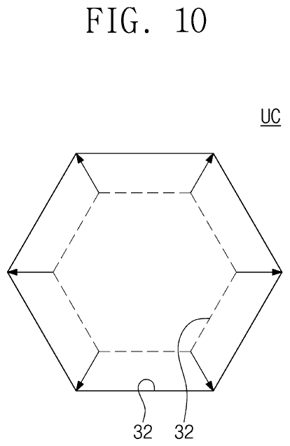

FIG. 10 is a conceptual diagram showing a process in which a unit pressure chamber of a membrane expands.

Referring to FIG. 10, the partition walls 32 that form the unit pressure chamber UC may receive compressed gas and expand outward. The unit pressure chamber UC has a regular hexagonal structure in a plan view, and thus, when the membrane expands, the unit pressure chamber UC may expand uniformly compared to regular triangular and square shape structures.

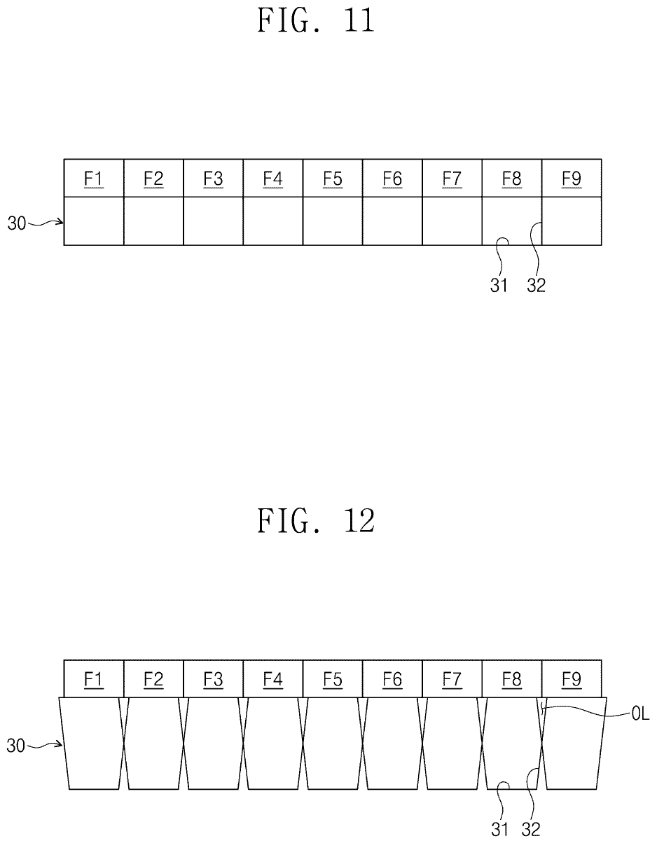

FIG. 11 is a conceptual diagram showing a membrane before expansion. FIG. 12 is a conceptual diagram showing the membrane after expansion.

Referring to FIGS. 11 and 12, after expansion of the membrane 30 compared to before expansion, the partition walls 32 may move in the horizontal direction and the pressing layer 31 may move downward. When the adjacent unit pressure chambers each expand, the partition walls 32 therebetween may have an overlap region OL in which pressures overlap each other. According to the inventive concept, when the adjacent unit pressure chambers UC expand, the pressing layer 31 below the overlap region OL may also press against the substrate W. As a result, not only a portion of the pressing layer 31 that forms the unit pressure chamber UC, but also the pressing layer 31 below a space between the unit pressure chambers UC may press against the substrate W. The partition walls 32 that form regular hexagonal shapes may form the unit pressure chambers UC having the same volume, and thus apply pressure onto the substrate W by controlling the pressures applied to the unit pressure chambers UC.

In contrast, according to a comparative example, a membrane may have partition walls having concentric circles. According to the comparative example, even if compressed gas of the same pressure is delivered to a single pressure chamber defined by partition walls, the level of pressure may vary depending on relative distance from the center of the circle. Also, when compressed gas is delivered to adjacent pressure chambers, a substrate below a portion between the pressure chambers may not be sufficiently pressed or may be excessively pressed. According to the comparative example, while a portion of the substrate may be excessively polished, another portion thereof may be insufficiently polished. Accordingly, it may be difficult to control a polishing profile. The inventive concept may improve the polishing profile with uniform polishing pressure compared to the comparative example.

The membrane according to the inventive concept may include the unit pressure chamber having the regular hexagonal shape which forms the honeycomb structure. The unit pressure chambers are configured to receive the compressed gas from the gas feeding lines of the polishing head and may thus apply pressure so that the substrate is polished uniformly.

Although the embodiments of the present invention have been described, it is understood that the present invention should not be limited to these embodiments but various changes and modifications can be made by one ordinary skilled in the art within the spirit and scope of the present invention as hereinafter claimed.

1. A membrane comprising:
a pressing layer; and
a plurality of partition walls extending upward from the pressing layer and connected to each other,
wherein the plurality of partition walls, together with the pressing layer, form a plurality of unit pressure chambers, each unit pressure chamber having a regular hexagonal shape in a plan view, and the plurality of unit pressure chambers form a honeycomb structure.

2. The membrane of claim 1, wherein both the pressing layer and the plurality of partition walls comprises elastic bodies.

3. The membrane of claim 2, wherein the elastic bodies comprise at least one of polyurethane, silicone rubber, or ethylene propylene diene rubber.

4. The membrane of claim 1, wherein the plurality of unit pressure chambers each have the same volume.

5. A chemical mechanical polishing apparatus comprising:
a polishing head;
a membrane mounted on bottom of the polishing head; and
a retainer ring connected to bottom edge of the polishing head and surrounding the membrane,
wherein the membrane comprises:
a pressing layer configured to press a substrate; and
partitions walls extending upward from the pressing layer,
wherein the partition walls form a plurality of unit pressure chambers, each unit pressure chamber having a regular hexagonal shape in a plan view, wherein the plurality of unit pressure chambers form a honeycomb structure, and wherein the polishing head comprises gas feeding lines configured to independently deliver compressed gas to the plurality of unit pressure chambers.

6. The chemical mechanical polishing apparatus of claim 5, further comprising a pressure regulator module including a plurality of pressure regulators, each pressure regulator of the pressure regulator module in fluid communication with a corresponding one of the gas feed lines to regulate pressure of the compressed gas within the corresponding gas feed line.

7. The chemical mechanical polishing apparatus of claim 6, further comprising:
a layer thickness sensor configured to measure a layer thickness of the substrate; and
a controller configured to control the pressure regulator module based on the measured layer thickness.

8. The chemical mechanical polishing apparatus of claim 7, wherein the controller is configured to independently control the pressure regulator module to supply the compressed gas within the gas feed lines with different pressures to provide compressed gas with different pressures to the plurality of unit pressure chambers.

9. The chemical mechanical polishing apparatus of claim 7, wherein the polishing head comprises:
a first common gas feeding line connected in common to a first subset of the gas feeding lines; and
a second common gas feeding line connected in common to a second subset of the gas feeding lines.

10. The chemical mechanical polishing apparatus of claim 9, wherein the controller is configured to control the pressure regulators module to supply the compressed gas independently to the first common gas feeding line and the second common gas feeding line at the same pressure.

11. The chemical mechanical polishing apparatus of claim 9, wherein the controller is configured to control the pressure regulator module to supply the compressed gas independently to the first common gas feeding line and the second common gas feeding line at different pressures.

12. The chemical mechanical polishing apparatus of claim 7, wherein the controller is configured to control the pressure regulator module to supply the compressed gas independently to a plurality of pressing zones which are arranged at different locations, and each of the plurality of pressing zones includes at least one unit pressure chamber.

13. The chemical mechanical polishing apparatus of claim 12, wherein the controller is configured to control the pressure regulator module to supply the compressed gas to a first unit pressure chamber and a second unit pressure chamber of a first pressing zone among the plurality of pressing zones at the same pressure.

14. The chemical mechanical polishing apparatus of claim 13, wherein the controller is configured to control the pressure regulator module to supply the compressed gas to the first unit pressure chamber and the second unit pressure chamber simultaneously.

15. The chemical mechanical polishing apparatus of claim 5, wherein each of the gas feeding lines comprises a valve which is configured to adjust an opening size of the gas feeding line.

16. A method of manufacturing a semiconductor device, comprising:
placing a substrate between a membrane of a polishing head of a chemical mechanical polishing apparatus and a polishing pad of the chemical mechanical polishing apparatus; and
polishing the substrate with the polishing pad, including expanding a region of the membrane to increase a pressing force of a target region of the substrate on the polishing pad,
wherein expanding the region of the membrane comprises independently supplying compressed gas to unit pressure chambers of the membrane.

17. The method of claim 16, wherein expanding the region of the membrane comprises independently supplying the compressed gas via gas feeding lines each connected to a respective one of the unit pressure chambers.

18. The method of claim 16, wherein expanding the region of the membrane comprises expanding a first pressing zone and a second pressing zone that are arranged at different locations, each of the first and second pressing zones comprises at least one unit pressure chamber, and expanding of the first pressing zone and the second pressing zone comprises supplying the first pressing zone with the compressed gas at higher pressure than the second pressing zone during a first time period, and supplying the second pressing zone with compressed gas at higher pressure than the first pressing zone during a second time period.

19. The method of claim18, wherein the pressing zones each comprise a plurality of unit pressure chambers that are organized into a first pressing zone and a second pressing zone that are arranged at different locations, and expanding the region of the membrane further comprises simultaneously supplying the first pressing zone and the second pressing zone with compressed gas at different pressures.

20. (canceled)

21. The method of claim 16, further comprising:
measuring a layer thickness of the substrate; and
expanding the region of the membrane by supplying the compressed gas based on the measured layer thickness.

22. (canceled)
